(19) United States
(12) Patent Application Publication
(10) Pub. No.: US 2010/0119973 A1
(43) Pub. Date: May 13, 2010

(54) POSITIVE PHOTOSENSITIVE RESIN COMPOSITION AND CURED FILM FORMING METHOD USING THE SAME

(75) Inventor: Satoshi Takita, Shizuoka (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/532,005

(22) PCT Filed: Mar. 27, 2008
(86) PCT No.: PCT/JP2008/056626

§ 371 Date: Sep. 18, 2009

(30) Foreign Application Priority Data
Mar. 27, 2007 (JP) 2007-081505
May 9, 2007 (JP) 2007-124402

(51) Int. Cl. G03F 7/20; G03F 7/004

(52) U.S. Cl. 430/281.1; 430/270.1; 430/326

(57) ABSTRACT

A positive photosensitive resin composition, includes: (A) a resin containing an acid-dissociable group having a specific acetal structure as defined in the specification, which is alkali-insoluble or sparingly alkali-soluble and becomes alkali-soluble when the acid-dissociable group is dissociated; (B) a compound capable of generating an acid upon irradiation with actinic rays or radiation; (C) a crosslinking agent; and (D) an adhesion aid, and a cured film forming method uses the same.

### TECHNICAL FIELD

The present invention relates to a positive photosensitive resin composition and a cured film forming method using the same. More specifically, the present invention relates to a positive photosensitive resin composition suitable for the formation of a flattening film, a protective film or an interlayer insulating film of electronic components such as liquid crystal display device, integrated circuit device, solid-state imaging device and organic EL, and a cured film forming method using the same.

### BACKGROUND ART

Conventionally, in electronic components such as liquid crystal display device, integrated circuit device, solid-state imaging device and organic EL, a photosensitive resin composition is generally used when forming a flattening film for imparting flatness to the surface of an electronic component, a protective film for preventing deterioration or damage of an electronic component, or an interlayer insulating film for keeping the insulating property. For example, in the production of a TFT-type liquid crystal display device, a back plate is prepared by providing a polarizing plate on a glass substrate, forming a transparent electrically conductive circuit layer such as ITO and a thin-film transistor (TFT), and coating an interlayer insulating film, a top plate is prepared by providing a polarizing plate on a glass substrate, forming, if desired, patterns of a black matrix layer and a color filter layer, and further sequentially forming a transparent electrically conductive circuit layer and an interlayer insulating film, and after disposing these back and top plates to face each other through a spacer, a liquid crystal is encapsulated between two plates. The photosensitive resin composition used here at the formation of an interlayer insulating film is required to be excellent in the sensitivity, residual film ratio, resolution, heat resistance, adhesion and transparency. Also, excellent aging stability during storage is further required of the photosensitive resin composition.

As regards the photosensitive resin composition, for example, JP-A-5-165214 has proposed a photosensitive resin composition comprising (A) a resin soluble in an aqueous alkali solution, which is a polymer of (a) an unsaturated carboxylic acid or an unsaturated carboxylic anhydride, (b) an epoxy group-containing radical polymerizable compound and (c) another radical polymerizable compound, and (B) a radiation-sensitive acid-generating compound, and JP-A-10-153854 has proposed a photosensitive resin composition comprising an alkali-soluble acryl-based polymer binder, a quinonediazide group-containing compound, a crosslinking agent, and a photoacid generator. However, these all are insufficient in the sensitivity, unexposed area residual film ratio, resolution and aging stability and are not satisfied for producing a high-quality liquid crystal display device. JP-A-2004-4669 has proposed a positive chemical amplification resist composition comprising a crosslinking agent, an acid generator and a resin having a protective group capable of being cleaved under the action of an acid, where the resin itself is insoluble or sparingly soluble in an aqueous alkali solution but becomes soluble in an aqueous alkali solution after cleavage of the protective group. However, this is insufficient in the adhesion and is not satisfied for producing a high-quality liquid crystal display device. In JP-A-2004-264623, a radiation-sensitive resin composition comprising a resin containing an acetal structure and/or a ketal structure as well as an epoxy group, and an acid generator is proposed, but the sensitivity is low and not satisfiable.

### DISCLOSURE OF THE INVENTION

An object of the present invention is to provide a positive photosensitive resin composition excellent in the sensitivity, resolution, residual film ratio and storage stability, and a cured film forming method using the same, which are a positive photosensitive resin composition and a cured film forming method using the same, ensuring that when the composition is cured, a cured film excellent in the heat resistance, adhesion, transmittance and the like is obtained.

The present inventors have made intensive studies to solve the above-described problems and have reached the present invention.

The present invention is as follows.

(1) A positive photosensitive resin composition, comprising:

(A) a resin having an acid-dissociable group represented by formula (1), which is alkali-insoluble or sparingly alkali-soluble and becomes alkali-soluble when the acid-dissociable group is dissociated;

(B) a compound capable of generating an acid upon irradiation with actinic rays at a wavelength of 300 nm or more;

(C) a crosslinking agent; and

(D) an adhesion aid:

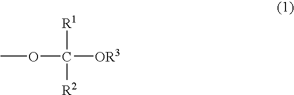

wherein R¹ and R² each independently represents a hydrogen atom, a linear or branched alkyl group which may be substituted or a cycloalkyl group which may be substituted, provided that a case where R¹ and R² both are a hydrogen atom is excluded;

R³ represents a linear or branched alkyl group which may be substituted, a cycloalkyl group which may be substituted or an aralkyl group which may be substituted; and

R¹ and R³ may combine to form a cyclic ether.

(2) The positive photosensitive resin composition as described in (1) above,

wherein the component (A) contains a constituent unit represented by formula (2) and a constituent unit represented by formula (3):

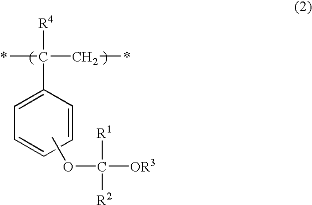

wherein R¹ and R² each independently represents a hydrogen atom, a linear or branched alkyl group which may be substituted or a cycloalkyl group which may be substituted, provided that a case where R¹ and R² both are a hydrogen atom is excluded;

R³ represents a linear or branched alkyl group which may be substituted, a cycloalkyl group which may be substituted or an aralkyl group which may be substituted;

R¹ and R³ may combine to form a cyclic ether; and

R⁴ represents a hydrogen atom or a methyl group:

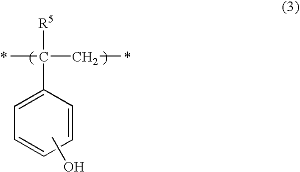

wherein R⁵ represents a hydrogen atom or a methyl group.

(3) The positive photosensitive resin composition as described in (1) or (2) above, comprising:

a compound represented by formula (4) as the component (B):

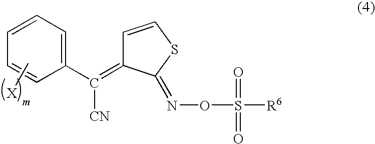

wherein R⁶ represents a linear or branched alkyl group which may be substituted, a cycloalkyl group which may be substituted or an aryl group which may be substituted;

X represents a linear or branched alkyl group which may be substituted, an alkoxy group which may be substituted or a halogen atom; and

m represents an integer of 0 to 3, and when m represents 2 or 3, a plurality of X's may be the same or different.

(4) The positive photosensitive resin composition as described in any of (1) to (3) above, comprising:

a compound having at least two structures represented by formula (5) as the component (C):

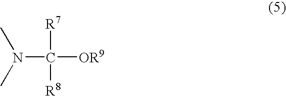

wherein R⁷ and R⁹ each independently represents a hydrogen atom, a linear or branched alkyl group or a cycloalkyl group; and

R⁹ represents a linear or branched alkyl group, a cycloalkyl group, an aralkyl group or an acyl group.

(5) The positive photosensitive resin composition as described in any of (1) to (3) above, comprising:

at least one compound selected from the group consisting of a compound represented by formula (6), a compound represented by formula (7) and a compound represented by formula (8) as the component (C):

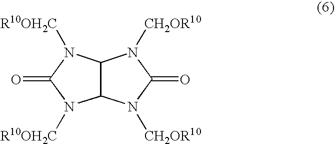

wherein R¹⁰ each independently represents a linear or branched alkyl group, a cycloalkyl group or an acyl group:

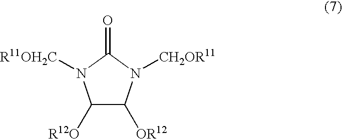

wherein R¹¹ and R¹² each independently represents a linear or branched alkyl group, a cycloalkyl group or an acyl group:

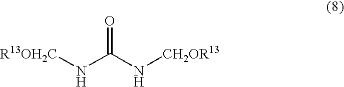

wherein R¹³ each independently represents a linear or branched alkyl group, a cycloalkyl group or an acyl group.

(6) A cured film forming method, comprising:

coating and drying the positive photosensitive resin composition as described in any of (1) to (5) above to form a film coating;

exposing the film coating through a mask by using actinic rays at a wavelength of 300 nm or more;

developing the film coating by using an alkali developer to form a pattern; and

heat-treating the obtained pattern.

(7) The cured film forming method as described in (6) above, which further comprises:

performing entire surface exposure after developing the film coating by using an alkali developer to form a pattern but before heat-treating the obtained pattern.

Preferred embodiments of the present invention are further described below.

(8) The positive photosensitive resin composition as described in any of (1) to (5) above,

wherein the component (C) is contained in an amount of 2 to 100 parts by mass per 100 parts by mass of the component (A).

(9) The positive photosensitive resin composition as described in any of (1) to (5) and (8) above,

wherein the component (D) is contained in an amount of 0.1 to 20 parts by mass per 100 parts by mass of the component (A).

### BEST MODE FOR CARRYING OUT THE INVENTION

The present invention is described in detail below.

Incidentally, in the present invention, when a group (atomic group) is denoted without specifying whether substituted or unsubstituted, the group includes both a group having no substituent and a group having a substituent. For example, an “alkyl group” includes not only an alkyl group having no substituent (unsubstituted alkyl group) but also an alkyl group having a substituent (substituted alkyl group).

(A) Resin Having an Acid-Dissociable Group Represented by Formula (1), which is Alkali-Insoluble or Sparingly Alkali-Soluble and Becomes Alkali-Soluble when the Acid-Dissociable Group is Dissociated

The positive photosensitive resin composition of the present invention contains a resin having an acid-dissociable group represented by the following formula (1), which is alkali-insoluble or sparingly alkali-soluble and becomes alkali-soluble when the acid-dissociable group is dissociated (sometimes referred to as the “component (A)”).

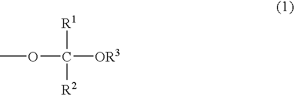

In formula (1), R¹ and R² each independently represents a hydrogen atom, a linear or branched alkyl group which may be substituted or a cycloalkyl group which may be substituted, provided that a case where R¹ and R² both are a hydrogen atom is excluded.

R³ represents a linear or branched alkyl group which may be substituted, a cycloalkyl group which may be substituted or an aralkyl group which may be substituted.

R¹ and R³ may combine to form a cyclic ether.

In formula (1), the linear or branched alkyl group of R¹ and R² is preferably a linear or branched alkyl group having a carbon number of 1 to 6. As a substituent, an alkoxy group having a carbon number of 1 to 6 or a halogen atom is preferred.

The cycloalkyl group of R¹ and R² is preferably a cycloalkyl group having a carbon number of 3 to 6. As a substituent, an alkyl group having a carbon number of 1 to 6, an alkoxy group having a carbon number of 1 to 6 or a halogen atom is preferred.

The linear or branched alkyl group of R³ is preferably a linear or branched alkyl group having a carbon number of 1 to 10. As a substituent, an alkoxy group having a carbon number of 1 to 6 or a halogen atom is preferred.

The cycloalkyl group of R³ is preferably a cycloalkyl group having a carbon number of 3 to 10. As a substituent, an alkyl group having a carbon number of 1 to 6, an alkoxy group having a carbon number of 1 to 6 or a halogen atom is preferred.

The aralkyl group of R³ is preferably an aralkyl group having a carbon number of 7 to 10. As a substituent, an alkyl group having a carbon number of 1 to 6, an alkoxy group having a carbon number of 1 to 6 or a halogen atom is preferred.

When R¹ and R³ combine to form a cyclic ether, R¹ and R³ preferably combine to form an alkylene chain having a carbon number of 2 to 5.

The component (A) of the present invention is characterized by having an acid-dissociable group represented by formula (1). The positive photosensitive composition of the present invention contains a crosslinking agent and therefore, when PEB (post exposure bake) is performed at a high temperature after image exposure, a crosslinking reaction occurs to make it impossible to effect the development. On the other hand, the acid-dissociable group represented by formula (1) of the present invention is low in the acid decomposition activating energy and readily decomposes in the presence of an acid, and PEB need not be performed at a high temperature. Accordingly, the acid-dissociable group can be decomposed by performing PEB at a relatively low temperature without causing a crosslinking reaction, and a positive image can be formed by the development.

The constituent unit having an acid-dissociable group represented by formula (1) includes those where a phenolic hydroxyl group such as hydroxystyrene or novolak is protected by an acetal group. The preferred constituent unit is an acid-dissociable group-containing constituent unit represented by the following formula (2), and examples thereof include 1-alkoxyalkoxystyrene, 1-(haloalkoxy)alkoxystyrene, 1-(aralkyloxy)alkoxystyrene and tetrahydropyranyloxystyrene. Among these, 1-alkoxyalkoxystyrene and tetrahydropyranyloxystyrene are preferred, and 1-alkoxyalkoxystyrene is more preferred.

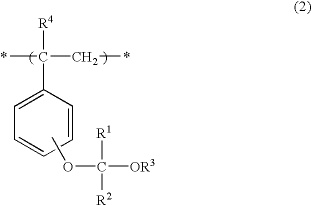

In formula (2), R¹ and R² each independently represents a hydrogen atom, a linear or branched alkyl group which may be substituted or a cycloalkyl group which may be substituted, provided that a case where R¹ and R² both are a hydrogen atom is excluded.

R³ represents a linear or branched alkyl group which may be substituted, a cycloalkyl group which may be substituted or an aralkyl group which may be substituted.

R¹ and R³ may combine to form a cyclic ether.

R⁴ represents a hydrogen atom or a methyl group.

R¹ to R³ in formula (2) have the same meanings as R¹ to R³ in formula (1).

The constituent unit represented by formula (2) may have a substituent such as alkyl group or alkoxy group on the benzene ring.

Specific examples of the constituent unit having an acid-dissociable group represented by formula (1) include p- or m-1-ethoxyethoxystyrene, p- or m-1-methoxyethoxystyrene, p- or m-1-n-butoxyethoxystyrene, p- or m-1-isobutoxyethoxystyrene, p- or m-1-(1,1-dimethylethoxy)ethoxystyrene, p- or m-1-(2-chloroethoxy)ethoxystyrene, p- or m-1-(2-ethylhexyloxy)ethoxystyrene, p- or m-1-n-propoxyethoxystryrene, p- or m-1-cyclohexyloxyethoxystyrene, p- or m-1-(2-cyclohexylethoxy)ethoxystyrene, and p- or m-1-benzyloxyethoxystyrene, and these may be used individually or in combination of two or more kinds thereof.

The copolymerization composition of the constituent unit having an acid-dissociable group represented by formula (1) is preferably from 10 to 90 mol %, more preferably from 20 to 50 mol %, based on all components.

The component (A) preferably has a constituent unit represented by the following formula (3):

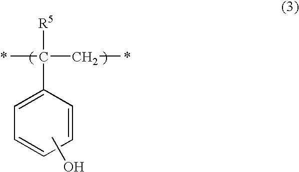

In formula (3), R⁵ represents a hydrogen atom or a methyl group.

The constituent unit represented by formula (3) may have a substituent such as alkyl group or alkoxy group on the benzene ring.

Examples of the constituent unit represented by formula (3) include hydroxystyrene and α-methylhydroxystyrene, with hydroxystyrene being preferred.

The copolymerization composition of the constituent unit represented by formula (3) is preferably from 30 to 90 mol %, more preferably from 50 to 80 mol %, based on all components.

In the component (A), if desired, a constituent unit other than the constituent unit represented by formula (2) and the constituent unit represented by formula (3) may be copolymerized. Examples of the constituent unit other than the constituent unit represented by formula (2) and the constituent unit represented by formula (3) include constituent units by styrene, tert-butoxy styrene, methylstyrene, α-methylstyrene, acetoxystyrene, α-methylacetoxystyrene, methoxystyrene, ethoxystyrene, chlorostyrene, methyl vinylbenzoate, ethyl vinylbenzoate, methyl acrylate, methyl methacrylate, ethyl acrylate, ethyl methacrylate, n-propyl acrylate, n-propyl methacrylate, isopropyl acrylate, isopropyl methacrylate, tert-butyl acrylate, tert-butyl methacrylate, 2-hydroxyethyl acrylate, 2-hydroxyethyl methacrylate, 2-hydroxypropyl acrylate, 2-hydroxypropyl methacrylate, benzyl acrylate, benzyl methacrylate, isobornyl acrylate, isobornyl methacrylate, glycidyl methacrylate and acrylonitrile, and these may be used individually or in combination of two or more kinds thereof.

The copolymerization composition of thus constituent unit is preferably 40 mol % or less, more preferably 20 mol % or less, based on all components.

The molecular weight of the component (A) is, in terms of polystyrene-reduced weight average molecular weight, preferably from 1,000 to 200,000, more preferably from 2,000 to 50,000.

As for the component (A), two or more kinds of resins containing different constituent units may be mixed and used, or two or more kinds of resins comprising the same constituent units and differing in the composition may be mixed and used.

The component (A) may be synthesized by various methods but, for example, may be synthesized by reacting a phenolic hydroxyl group-containing resin with a vinyl ether in the presence of an acid catalyst.

(B) Compound Capable of Generating an Acid Upon Irradiation with Actinic Rays at a Wavelength of 300 nm or More

The compound capable of generating an acid upon irradiation with actinic rays at a wavelength of 300 nm or more (sometimes referred to as a “component (B)”) for use in the present invention is not limited in its structure as long as the compound is sensitized to actinic rays at a wavelength of 300 nm or more and generates an acid. As for the acid generated, a compound which generates an acid having a pKa of 3 or less is preferred, and a compound which generates a sulfonic acid is more preferred. Examples thereof include a sulfonium salt, an iodonium salt, a diazomethane compound, an imidosulfonate compound, an oximesulfonate compound and a quinonediazide compound, and these may be used individually or in combination of two or more kinds thereof.

Among the components (B), an oximesulfonate compound is preferred, and a compound represented by the following formula (4) is more preferred.

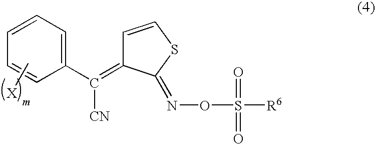

In formula (4), R⁶ represents a linear or branched alkyl group which may be substituted, a cycloalkyl group which may be substituted or an aryl group which may be substituted.

X represents a linear or branched alkyl group which may be substituted, an alkoxy group which may be substituted or a halogen atom.

m represents an integer of 0 to 3. When m is 2 or 3, the plurality of X's may be the same or different.

In formula (4), the alkyl group of R⁶ is preferably a linear or branched alkyl group having a carbon number of 1 to 10. The alkyl group of R⁶ may be substituted by an alkoxy group (preferably having a carbon number of 1 to 10) or an alicyclic group (including a crosslinked alicyclic group such as 7,7-dimethyl-2-oxonorbornyl group; preferably a bicycloalkyl group).

The cycloalkyl group of R⁶ is preferably a cycloalkyl group having a carbon number of 3 to 10.

The aryl group of R⁶ is preferably an aryl group having a carbon number of 6 to 11, more preferably a phenyl group or a naphthyl group. The aryl group of R⁶ may be substituted by an alkyl group (preferably having a carbon number of 1 to 5), an alkoxy group (preferably a carbon number of 1 to 5), or a halogen atom.

The alkyl group of X is preferably a linear or branched alkyl group having a carbon number of 1 to 4.

The alkoxy group of X is preferably a linear or branched alkoxy group having a carbon number of 1 to 4.

The halogen atom of X is preferably a chlorine atom or a fluorine atom.

m is preferably 0 or 1.

Above all, preferred is a compound where in formula (3), m is 1, X is a methyl group and the substitution site of X is the ortho position.

The compound represented by formula (4) is more preferably a compound represented by the following formula (4a):

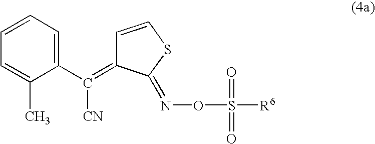

In formula (4a), R⁶ has the same meaning as R⁶ in formula (4).

Specific examples of the oximesulfonate compound include Compound (10), Compound (11), Compound (12) and Compound (13) shown below, and these may be used individually or in combination of two or more kinds thereof. Also, another kind of the component (B) may be used in combination.

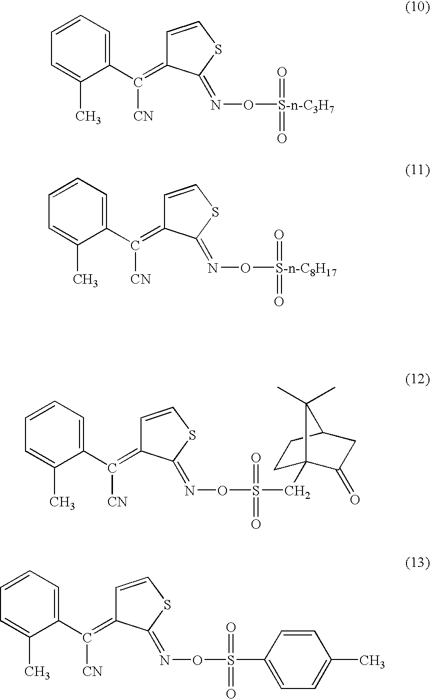

Compound (10), Compound (11), Compound (12) and Compound (13) are available as a commercial product.

### (C) Crosslinking Agent

Examples of the crosslinking agent (sometimes referred to as a “component (C)”) include a compound having at least two structures represented by the following formula (5):

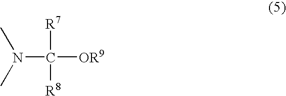

In formula (5), R⁷ and R⁸ each independently represents a hydrogen atom, a linear or branched alkyl group or a cycloalkyl group.

R⁹ represents a linear or branched alkyl group, a cycloalkyl group, an aralkyl group or an acyl group.

In formula (5), the linear or branched alkyl group of R⁷, R⁸ and R⁹ is preferably a linear or branched alkyl group having a carbon number of 1 to 10.

The cycloalkyl group of R⁷, R⁸ and R⁹ is preferably a cycloalkyl group having a carbon number of 3 to 10.

The aralkyl group of R⁹ is preferably an aralkyl group having a carbon number of 7 to 10.

The acyl group of R⁹ is preferably an acyl group having a carbon number of 2 to 10.

The crosslinking agent is preferably an alkoxymethylated urea resin or an alkoxymethylated glycol uril resin, more preferably an alkoxymethylated glycol uril resin.

The crosslinking agent is more preferably a compound represented by the following formula (6), (7) or (8):

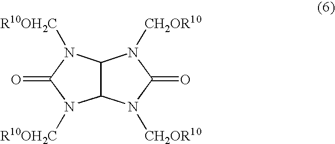

In formula (6), R¹⁰ each independently represents a linear or branched alkyl group, a cycloalkyl group or an acyl group.

In formula (6), the linear or branched alkyl group of R¹⁰ is preferably a linear or branched alkyl group having a carbon number of 1 to 6.

The cycloalkyl group of R¹⁰ is preferably a cycloalkyl group having a carbon number of 3 to 6.

The acyl group of R¹⁰ is preferably an acyl group having a carbon number of 2 to 6.

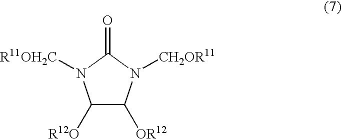

In formula (7), R¹¹ and R¹² each independently represents a linear or branched alkyl group, a cycloalkyl group or an acyl group.

In formula (7), the linear or branched alkyl group of R¹¹ and R¹² is preferably a linear or branched alkyl group having a carbon number of 1 to 6.

The cycloalkyl group of R¹¹ and R¹² is preferably a cycloalkyl group having a carbon number of 3 to 6.

The acyl group of R¹¹ and R¹² is preferably an acyl group having a carbon number of 2 to 6.

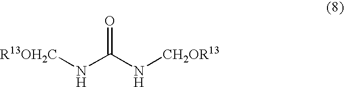

In formula (8), R¹³ each independently represents a linear or branched alkyl group, a cycloalkyl group or an acyl group.

In formula (8), the linear or branched alkyl group of R¹³ is preferably a linear or branched alkyl group having a carbon number of 1 to 6.

The cycloalkyl group of R¹³ is preferably a cycloalkyl group having a carbon number of 3 to 6.

The acyl group of R¹³ is preferably an acyl group having a carbon number of 2 to 6.

The component (C) is available as a commercial product.

### (D) Adhesion Aid

The adhesion aid (D) for use in the present invention is a compound for enhancing the adhesion between an inorganic material working out to the substrate, for example, a silicon compound such as silicon, silicon oxide and silicon nitride, or a metal such as gold, copper and aluminum, and an insulating film. Specific examples thereof include a silane coupling agent and a thiol-based compound.

The silane coupling agent as the adhesion aid for use in the present invention is used for the purpose of reforming the interface and is not particularly limited, and a known silane coupling agent can be used.

Preferred examples of the silane coupling agent include γ-glycidoxypropyltrialkoxysilane, γ-glycidoxypropylalkyldialkoxysilane, γ-methacryloxypropyltrialkoxysilane, γ-methacryloxypropylalkyldialkoxysilane, γ-chloropropyltrialkoxysilane, γ-mercaptopropyltrialkoxysilane, β-(3,4-epoxycyclohexyl)ethyltrialkoxysilane and vinyltrialkoxysilane.

Among these, γ-glycidoxypropyltrialkoxysilane and γ-methacryloxypropyltrialkoxysilane are more preferred, and γ-glycidoxypropyltrialkoxysilane is still more preferred.

These silane coupling agents may be used individually or in combination of two or more kinds thereof. The silane coupling agent is effective not only for enhancing the adhesion to the substrate but also for adjusting the taper angle with the substrate.

As for the mixing ratio of the component (A), the component (B), the component (C) and the component (D) in the positive photosensitive resin composition of the present invention, per 100 parts by mass of the component (A), the component (B) is preferably from 0.01 to 10 parts by mass, more preferably from 0.05 to 2 parts by mass, the component (C) is preferably from 2 to 100 parts by mass, more preferably from 10 to 30 parts by mass, and the component (D) is preferably from 0.1 to 20 parts by mass, more preferably from 0.5 to 10 parts by mass. (In this specification, mass ratio is equal to weight ratio.)

### Other Components:

In the positive photosensitive resin composition of the present invention, in addition to the component (A), the component (B), the component (C) and the component (D), for example, a basic compound, a surfactant, an ultraviolet absorbent, a sensitizer, a plasticizer, a thickener, an organic solvent, an adhesion accelerator, and an organic or inorganic precipitation inhibitor may be added, if desired.

### Basic Compound:

The basic compound which is used may be arbitrarily selected from those used for a chemical amplification resist. Examples thereof include an aliphatic amine, an aromatic amine, a heterocyclic amine, a quaternary ammonium hydroxide and a quaternary ammonium carboxylate.

Examples of the aliphatic amine include trimethylamine, diethylamine, triethylamine, di-n-propylamine, tri-n-propylamine, di-n-pentylamine, tri-n-pentylamine, diethanolamine, triethanolamine, dicyclohexylamine and dicyclohexylmethylamine.

Examples of the aromatic amine include aniline, benzylamine, N,N-dimethylaniline and diphenylamine.

Examples of the heterocyclic amine include pyridine, 2-methylpyridine, 4-methylpyridine, 2-ethylpyridine, 4-ethylpyridine, 2-phenylpyridine, 4-phenylpyridine, N-methyl-4-phenylpyridine, 4-dimethylaminopyridine, imidazole, benzimidazole, 4-methylimidazole, 2-phenylbenzimidazole, 2,4,5-triphenylimidazole, nicotine, nicotinic acid, nicotinic acid amide, quinoline, 8-oxyquinoline, pyrazine, pyrazole, pyridazine, purine, pyrrolidine, piperidine, piperazine, morpholine, 4-methylmorpholine, 1,5-diazabicyclo[4,3,0]-5-nonene, and 1,8-diazabicyclo[5,3,0]-7-undecene.

Examples of the quaternary ammonium hydroxide include tetramethylammonium hydroxide, tetraethylammonium hydroxide, tetra-n-butylammonium hydroxide and tetra-n-hexylammonium hydroxide.

Examples of the quaternary ammonium carboxylate include tetramethylammonium acetate, tetramethylammonium benzoate, tetra-n-butylammonium acetate and tetra-n-butylammonium benzoate.

The blending amount of the basic compound is preferably from 0.001 to 1 parts by mass, more preferably from 0.005 to 0.2 parts by mass, per 100 parts by mass of the component (A).

### Surfactant:

As for the surfactant, any of anionic, cationic, nonionic and amphoteric surfactants may be used, but the preferred surfactant is a nonionic surfactant. Examples of the nonionic surfactant which can be used include polyoxyethylene higher alkyl ethers, polyoxyethylene higher alkyl phenyl ethers, higher fatty acid diesters of polyoxyethylene glycol, silicone-containing or fluorine-containing surfactants, and Series under a trade name such as KPi (produced by Shin-Etsu Chemical Co., Ltd.), Polyflow (produced by Kyoeisha Chemical Co., Ltd.), EFtop (produced by JEMCO), Megafac (produced by Dainippon Ink and Chemicals, Inc.), Florad (produced by Sumitomo 3M, Inc.), Asahi Guard and Surflon (produced by Asahi Glass Co., Ltd.).

The surfactants may be used individually or as a mixture of two or more kinds thereof.

The blending amount of the surfactant is usually 10 parts by mass or less, preferably from 0.01 to 10 parts by mass, more preferably from 0.05 to 2 parts by mass, per 100 parts by mass of the component (A).

### Plasticizer:

Examples of the plasticizer include dibutyl phthalate, dioctyl phthalate, didodecyl phthalate, polyethylene glycol, glycerin, dimethyl glycerin phthalate, dibutyl tartrate, dioctyl adipate and triacetylglycerin.

The blending amount of the plasticizer is preferably from 0.1 to 30 parts by mass, more preferably from 1 to 10 parts by mass, per 100 parts by mass of the component (A).

### Solvent:

The positive photosensitive composition of the present invention is dissolved in a solvent and used as a solution. Examples of the solvent used for the positive photosensitive composition of the present invention include:

(a) ethylene glycol monoalkyl ethers such as ethylene glycol monomethyl ether, ethylene glycol monoethyl ether, ethylene glycol monopropyl ether and ethylene glycol monobutyl ether;

(b) ethylene glycol dialkyl ethers such as ethylene glycol dimethyl ether, ethylene glycol diethyl ether and ethylene glycol dipropyl ether;

(c) ethylene glycol monoalkyl ether acetates such as ethylene glycol monomethyl ether acetate, ethylene glycol monoethyl ether acetate, ethylene glycol monopropyl ether acetate and ethylene glycol monobutyl ether acetate;

(d) propylene glycol monoalkyl ethers such as propylene glycol monomethyl ether, propylene glycol monoethyl ether, propylene glycol monopropyl ether and propylene glycol monobutyl ether;

(e) propylene glycol dialkyl ethers such as propylene glycol dimethyl ether, propylene glycol diethyl ether, diethylene glycol monomethyl ether and diethylene glycol monoethyl ether;

(f) propylene glycol monoalkyl ether acetates such as propylene glycol monomethyl ether acetate, propylene glycol monoethyl ether acetate, propylene glycol monopropyl ether acetate and propylene glycol monobutyl ether acetate;

(g) diethylene glycol dialkyl ethers such as diethylene glycol dimethyl ether, diethylene glycol diethyl ether acetate and diethylene glycol ethyl methyl ether;

(h) diethylene glycol monoalkyl ether acetates such as diethylene glycol monomethyl ether acetate, diethylene glycol monoethyl ether acetate, diethylene glycol monopropyl ether acetate and diethylene glycol monobutyl ether acetate;

(i) dipropylene glycol monoalkyl ethers such as dipropylene glycol monomethyl ether, dipropylene glycol monoethyl ether, dipropylene glycol monopropyl ether and dipropylene glycol monobutyl ether;

(j) dipropylene glycol dialkyl ethers such as dipropylene glycol dimethyl ether, dipropylene glycol diethyl ether and dipropylene glycol ethyl methyl ether;

(k) dipropylene glycol monoalkyl ether acetates such as dipropylene glycol monomethyl ether acetate, dipropylene glycol monoethyl ether acetate, dipropylene glycol monopropyl ether acetate and dipropylene glycol monobutyl ether acetate;

(l) lactic acid esters such as methyl lactate, ethyl lactate, n-propyl lactate, isopropyl lactate, n-butyl lactate, isobutyl lactate, n-amyl lactate and isoamyl lactate;

(m) aliphatic carboxylic acid esters such as n-butyl acetate, isobutyl acetate, n-amyl acetate, isoamyl acetate, n-hexyl acetate, 2-ethylhexyl acetate, ethyl propionate, n-propyl propionate, isopropyl propionate, n-butyl propionate, isobutyl propionate, methyl butyrate, ethyl butyrate, n-propyl butyrate, isopropyl butyrate, n-butyl butyrate and isobutyl butyrate;

(n) other esters such as ethyl hydroxyacetate, ethyl 2-hydroxy-2-methylpropionate, ethyl 2-hydroxy-3-methylbutyrate, ethyl methoxyacetate, ethyl ethoxyacetate, methyl 3-methoxypropionate, ethyl 3-methoxypropionate, methyl 3-ethoxypropionate, ethyl 3-ethoxypropionate, 3-methoxybutyl acetate, 3-methyl-3-methoxybutyl acetate, 3-methyl-3-methoxybutyl propionate, 3-methyl-3-methoxybutyl butyrate, methyl acetoacetate, ethyl acetoacetate, methyl pyruvate and ethyl pyruvate;

(o) ketones such as methyl ethyl ketone, methyl propyl ketone, methyl n-butyl ketone, methyl isobutyl ketone, 2-heptanone, 3-heptanone, 4-heptanone and cyclohexanone;

(p) amides such as N-methylformamide, N,N-dimethylformamide, N-methylacetamide, N,N-dimethylacetamide and N-methylpyrrolidone; and

(q) lactones such as γ-butyrolactone.

Also, a solvent such as benzyl ethyl ether, dihexyl ether, ethylene glycol monophenyl ether acetate, diethylene glycol monomethyl ether, diethylene glycol monoethyl ether, isophorone, caproic acid, caprylic acid, 1-octanol, 1-nonal, benzyl alcohol, anisole, benzyl acetate, ethyl benzoate, diethyl oxalate, diethyl maleate, ethylene carbonate and propylene carbonate may be further added, if desired, to the solvent above.

One solvent may be used alone, or two or more kinds may be mixed and used.

The blending amount of the solvent is usually from 50 to 3,000 parts by mass, preferably from 100 to 2,000 parts by mass, more preferably from 150 to 1,000 parts by mass, per 100 parts by mass of the component (A).

By virtue of using a positive photosensitive resin composition containing the component (A), the component (B), the component (C) and the component (D), a positive photosensitive resin composition excellent in the sensitivity, residual film ratio, resolution and aging stability can be provided, which is a positive photosensitive resin composition ensuring that when cured, a cured film excellent in the insulating property, flatness, heat resistance, adhesion, transparency and the like is obtained.

The cured film forming method using the positive photosensitive resin composition of the present invention is described below.

The positive photosensitive resin composition of the present invention is coated on a substrate and heated, and a film coating is thereby formed on the substrate. When the obtained film coating is irradiated with actinic rays at a wavelength of 300 nm or more, the component (B) decomposes and an acid is generated. By the catalytic action of the generated acid, the acid-dissociable group represented by formula (1) contained in the component (A) dissociates through a hydrolysis reaction and a phenolic hydroxyl group is produced. The reaction formula of this hydrolysis reaction is shown below.

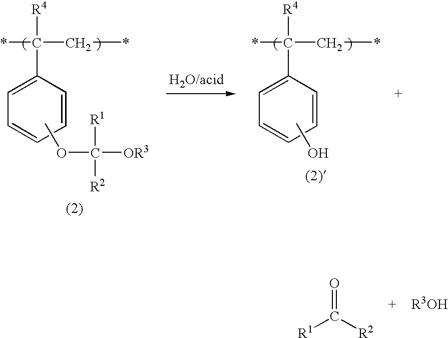

In order to accelerate the hydrolysis reaction, post exposure bake may be performed, if desired.

The phenolic hydroxyl group readily dissolves in an alkali developer and therefore, is removed by development, and a positive image is obtained.

The obtained positive image is heated at a high temperature to crosslink the component (A) and the crosslinking agent (the component (C)), whereby a cured film can be formed. The heating at a high temperature is performed usually at 150° C. or more, preferably at 180° C. or more, more preferably from 200 to 250° C.

When a step of irradiating the entire surface with actinic rays is added before the high-temperature heating step, the crosslinking reaction can be accelerated by an acid generated upon irradiation with actinic rays.

The cured film forming method using the positive photosensitive resin composition of the present invention is specifically described below.

### Preparation Method of Composition Solution:

The component (A), the component (B), the component (C), the component (D) and other components to be blended are mixed at a predetermined ratio by an arbitrary method and dissolved with stirring to prepare a composition solution. For example, the composition solution may also be prepared by previously dissolving each component in a solvent to prepare a solution and mixing these solutions at a predetermined ratio. The composition solution prepared in this way may be filtered using a filter or the like having a pore size of 0.2 μm and then used.

### Formation Method of Film Coating:

The composition solution is coated on a predetermined substrate and the solvent is removed by heating (hereinafter, referred to as “prebake”), whereby a desired film coating can be formed. Examples of the substrate include, for example, in the production of a liquid crystal display device, a glass plate having provided thereon a polarizing plate, where a black matrix layer and a color filter layer are further provided, if desired, and a transparent electrically conductive circuit layer is further provided thereon. The coating method on the substrate is not particularly limited and, for example, a method such as spraying method, roll coating method and rotary coating method may be used. Also, the heating conditions at the prebake vary depending on the kind of each component and the blending ratio but are approximately at 80 to 130° C. for 30 to 120 seconds.

### Pattern Forming Method:

The substrate having provided thereon the film coating is irradiated with actinic rays through a mask having a predetermined pattern and after performing, if desired, a heat treatment (PEB), the exposed area is removed using a developer to form an image pattern.

For the irradiation of actinic rays, a low-pressure mercury lamp, a high-pressure mercury lamp, an ultrahigh-pressure mercury lamp, a chemical lamp, an excimer laser generator or the like may be used, but an actinic ray at a wavelength of 300 nm or more, such as g-line, i-line and h-line, is preferred. Also, if desired, the irradiation light may be adjusted through a spectral filter such as long wavelength cut filter, short wavelength cut filter and band pass filter.

As regards the developer, there may be used an aqueous solution of, for example, alkali metal hydroxides such as lithium hydroxide, sodium hydroxide and potassium hydroxide; alkali metal carbonates such as sodium carbonate and potassium carbonate; alkali metal bicarbonates such as sodium bicarbonate and potassium bicarbonate; ammonium hydroxides such as tetramethylammonium hydroxide, tetraethylammonium hydroxide and choline hydroxide; sodium silicate, or sodium metasilicate. Also, an aqueous solution obtained by adding a water-soluble organic solvent such as methanol or ethanol and a surfactant in appropriate amounts to the above-described aqueous solution of alkalis may be used.

The development time is usually from 30 to 180 seconds, and the development method may be any of paddle, dip and the like. After the development, washing with running water is performed for 30 to 90 seconds, whereby a desired pattern can be formed.

### Crosslinking Step:

The substrate having formed thereon a pattern is irradiated with actinic rays to generate an acid from the component (B) present in the unexposed area. Thereafter, a heat treatment is performed using a heating device such as hot plate or oven at a predetermined temperature, for example, at 180 to 250° C., for a predetermined time, for example, for 5 to 30 minutes on a hot plate or for 30 to 90 minutes in an oven, to effect the crosslinking of the component (A) by the component (C), whereby a protective film or interlayer insulating film excellent in the heat resistance, hardness and the like can be formed.

In this step, the cured film may also be formed by performing the heat treatment without irradiating actinic rays or radiation. Furthermore, the transparency can be enhanced by performing the heat treatment in a nitrogen atmosphere.

### EXAMPLES

The present invention is described in greater detail below by referring to Examples, but the present invention is not limited to these Examples.

### Examples 1 to 9 and Comparative Examples 1 to 4

### (1) Preparation of Positive Photosensitive Resin Composition Solution

The components shown in Table 1 below were mixed to obtain a uniform solution, and the obtained solution was filtered through a polytetrafluoroethylene-made filter of 0.2 μm to prepare a positive photosensitive resin composition solution.

### (2) Evaluation of Storage Stability

The viscosity at 23° C. of the positive photosensitive resin composition solution was measured using an E-type viscometer manufactured by Toki Sangyo Co., Ltd. Also, the viscosity of the composition after storage in a constant temperature bath at 23° C. for one month was measured. The storage stability was rated “A” when the increase of viscosity after storage at room temperature for one month with respect to the viscosity after the preparation was less than 5%, and rated “B” when 5% or more. The results are shown in Table 2 below.

### (3) Evaluation of Sensitivity, Resolution and Residual Film Ratio at Development

The positive photosensitive resin composition solution was rotary coated on a silicon wafer having a silicon oxide film and then prebaked on a hot plate at 100° C. for 60 seconds to form a film coating of 2 μm in thickness.

The film coating was then exposed through a predetermined mask by using an i-line stepper (FPA-3000i5+, manufactured by Canon Inc.), and baked at 50° C. for 60 seconds. Next, the film coating was developed with an alkali developer shown in Table 2 (an aqueous 2.38 mass % or 0.4 mass % tetramethylammonium hydroxide solution) at 23° C. for 60 seconds and then rinsed with ultrapure water for one minute. The optimal exposure dose (Eopt) when resolving a 0.5-μm line-and-space at 1:1 by these operations was taken as the sensitivity.

The minimum line width resolved by exposure with the optimal exposure dose was defined as the resolution.

The film thickness of the unexposed area after development was measured and by determining the ratio to the film thickness after coating (film thickness of unexposed area after development film thickness after coating), the residual film ratio at the development was evaluated.

The evaluation results of sensitivity, resolution and residual film ratio at development are shown in Table 2.

### (4) Evaluation of Heat Resistance, Transmittance and Adhesion

A film coating was formed in the same manner as in (3) above except that in (3) above, a transparent substrate (Corning 1737, produced by Corning Inc.) was used in place of the silicon wafer having a silicon oxide film. The film coating was exposed by using a predetermined proximity exposure device (UX-1000SM, manufactured by Ushio Inc.) and using an ultraviolet ray having a light intensity of 18 mW/cm² at 365 nm while tightly contacting a predetermined mask, then developed with an alkali developer shown in Table 2 (an aqueous 2.38 mass % or 0.4 mass % tetramethylammonium hydroxide solution) at 23° C. for 60 seconds and rinsed with ultrapure water for one minute. By these operations, a pattern where a 10-μm line-and-space became 1:1 was formed. The obtained pattern was further subjected to entire surface exposure for 100 seconds and then heated in an oven at 220° C. for one hour to form a heat-cured film on the glass substrate.

The evaluation of heat resistance was performed by measuring the rate of change in the bottom dimension between before and after the heat curing (1-bottom dimension of heat-cured film bottom dimension after development)×100(%). The heat resistance was rated “A” when the rate of change is less than 5%, and rated “B” when 5% or more.

The transmittance in the unexposed portion (the portion corresponding to the unexposed area at the exposure through a mask) of the heat-cured film obtained was measured by a spectrophotometer (U-3000, manufactured by Hitachi, Ltd.) in the wavelength range of 400 to 800 nm. The transmittance was rated “A” when the minimum transmittance was more than 95%, rated “B” when from 90 to 95%, and rated “C” when less than 90%.

The unexposed portion (the portion corresponding to the unexposed area at the exposure through a mask) of the heat-cured film was incised vertically and horizontally by a cutter at intervals of 1 mm, and a tape peeling test was performed using Scotch Tape. The adhesion between the cured film and the substrate was evaluated from the area of the cured film transferred to the back surface of the tape. The adhesion was rated “A” when the area was less than 1%, rated “B” when from 1 to less than 5%, and rated “C” when 5% or more.

The evaluation results of heat resistance, transmittance and adhesion are shown in Table 2.

TABLE 1

| | Component | | Component | | Component | | Component | | Basic | | | |
|---|---|---|---|---|---|---|---|---|---|---|---|---|
| | (A) | | (B) | | (C) | | (D) | | Compound | | Solvent | |
| | | parts | | parts | | parts | | parts | | parts by | | parts by |
| | kind | by mass | kind | by mass | kind | by mass | kind | by mass | kind | mass | kind | mass |
| Example 1 | A-1 | 100 | B-1 | 0.2 | C-1 | 18 | D-1 | 2.4 | E-1 | 0.02 | F-1 | 300 |
| Example 2 | A-2 | 100 | B-2 | 0.22 | C-2 | 20 | D-1 | 2.4 | E-2 | 0.02 | F-2 | 300 |
| Example 3 | A-3 | 100 | B-3 | 0.23 | C-1 | 18 | D-1 | 2.4 | E-1 | 0.02 | F-3 | 300 |
| Example 4 | A-4 | 100 | B-4 | 0.2 | C-1 | 18 | D-1 | 2.4 | E-2 | 0.02 | F-1 | 300 |
| Example 5 | A-5 | 100 | B-1 | 0.2 | C-1 | 18 | D-2 | 2.4 | E-1 | 0.02 | F-1 | 300 |
| Example 6 | A-6 | 100 | B-1 | 0.2 | C-1 | 18 | D-3 | 2.4 | E-1 | 0.02 | F-1 | 300 |
| Example 7 | A-7 | 100 | B-1 | 0.2 | C-1 | 18 | D-1 | 2.4 | E-1 | 0.02 | F-1 | 300 |
| Example 8 | A-8 | 100 | B-1 | 0.2 | C-1 | 18 | D-1 | 2.4 | E-1 | 0.02 | F-1 | 300 |
| Example 9 | A-1 | 100 | B-1 | 0.25 | C-1 | 18 | D-1 | 2.4 | E-1 | 0.02 | F-1 | 300 |
| Comparative | A-1 | 100 | B-1 | 0.2 | — | — | D-1 | 2.4 | E-1 | 0.02 | F-1 | 300 |
| Example 1 | | | | | | | | | | | | |
| Comparative | A-2 | 100 | B-1 | 0.2 | C-1 | 18 | — | — | E-1 | 0.02 | F-1 | 300 |
| Example 2 | | | | | | | | | | | | |
| Comparative | A-9 | 100 | B-5 | 10 | — | — | — | — | — | — | F-3 | 257 |
| Example 3 | | | | | | | | | | | | |
| Comparative | A-9 | 100 | B-5 | 5 | — | — | — | — | — | — | F-3 | 245 |
| Example 4 | | | | | | | | | | | | |

The component (A), the component (B), the component (C), the component (D), the basic compound and the solvent shown in Table 1 are as follows.

### Component (A):

The numerical value on the right side of the constituent unit indicates the molar ratio of the constituent unit.

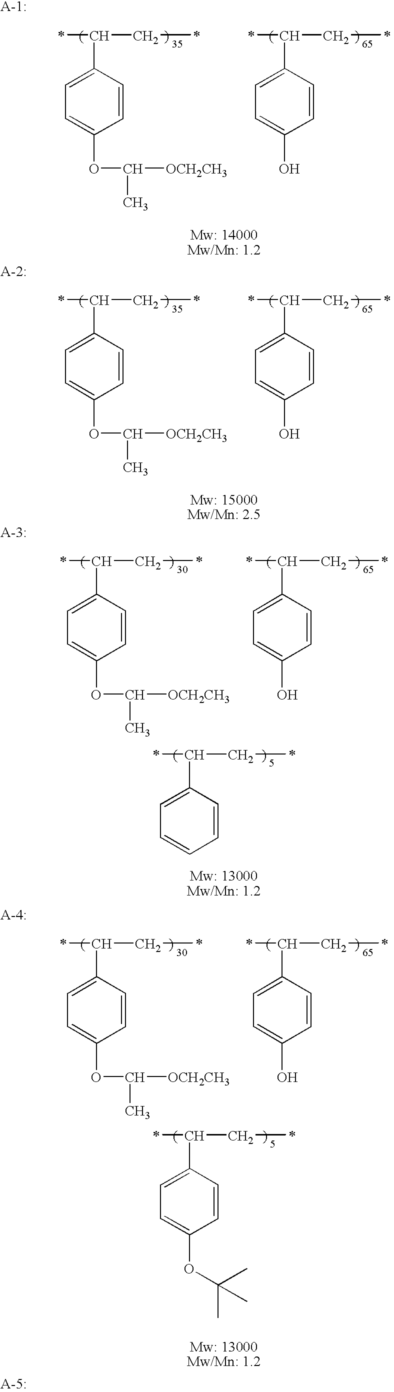

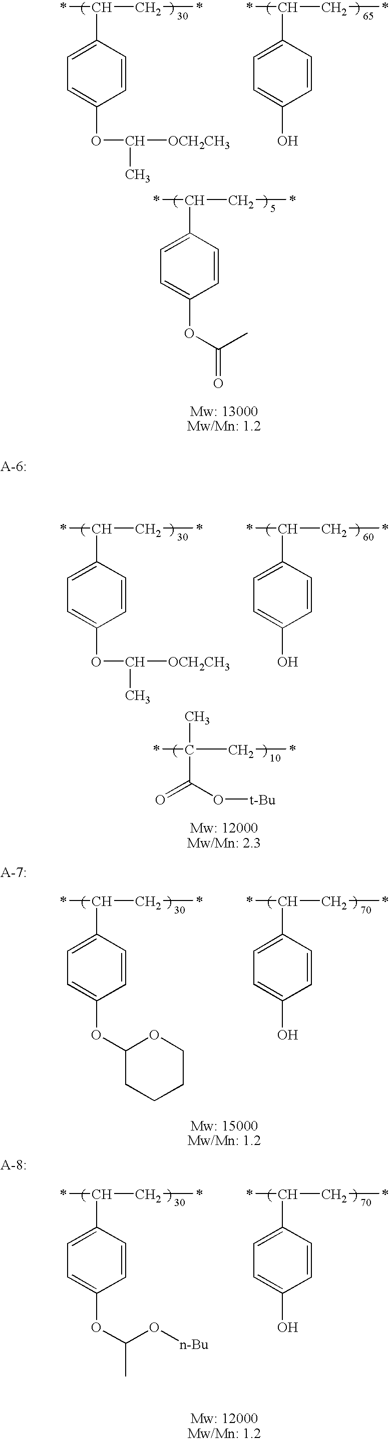

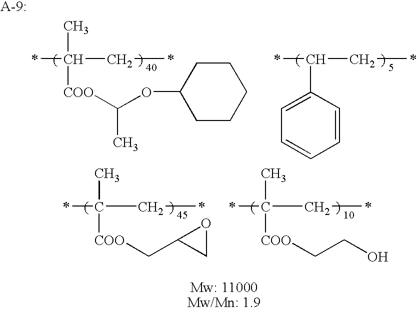

The resin of (A-9) was synthesized according to Synthesis Example 1 of JP-A-2004-264623.

### Component (B):

B-1: CGI-1397 (produced by Ciba Specialty Chemicals Corp.)

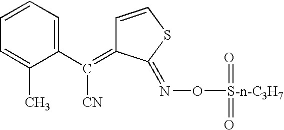

B-2: CGI-1325 (produced by Ciba Specialty Chemicals Corp.)

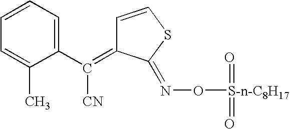

B-3: CGI-1380 (produced by Ciba Specialty Chemicals Corp.)

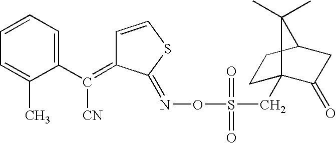

B-4: CGI-1311 (produced by Ciba Specialty Chemicals Corp.)

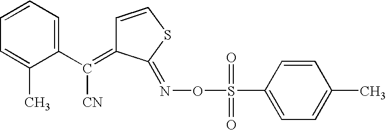

B-5: 4,7-di-n-butoxy-1-naphthyltetrahydrothiophenium trifluoromethanesulfonate

### Component (C):

C-1: MX-270 (produced by Sanwa Chemical Co., Ltd.)

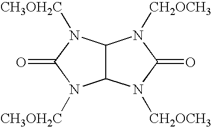

C-2: MX-280 (produced by Sanwa Chemical Co., Ltd.)

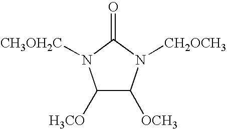

### Component (D):

D-1: γ-glycidoxypropyltrimethoxysilane
D-2: β-(3,4-epoxycyclohexyl)ethyltrimethoxysilane
D-3: γ-methacryloxypropyltrimethoxysilane

### Basic Compound:

E-1: 4-dimethylaminopyridine
E-2: 1,5-diazabicyclo[4,3,0]-5-nonene

### Solvent:

F-1: propylene glycol monomethyl ether acetate
F-2: diethylene glycol dimethyl ether
F-3: diethylene glycol ethyl methyl ether

TABLE 2

| | Concentration | Sensitivity | | Residual | | | | |
|---|---|---|---|---|---|---|---|---|
| | of Developer | (Eopt) | Resolution | Film Ratio | Heat | | | Storage |
| | (mass %) | (mJ/cm²) | (μm) | (%) | Rsistance | Adhesion | Transmittance | Stability |
| Example 1 | 2.38 | 50 | 0.43 | 100 | A | A | A | A |
| Example 2 | 2.38 | 53 | 0.45 | 99 | A | A | A | A |
| Example 3 | 2.38 | 52 | 0.45 | 100 | A | A | A | A |
| Example 4 | 2.38 | 53 | 0.44 | 99 | A | A | A | A |
| Example 5 | 2.38 | 55 | 0.45 | 100 | A | A | A | A |
| Example 6 | 2.38 | 50 | 0.44 | 99 | A | A | A | A |
| Example 7 | 2.38 | 58 | 0.46 | 99 | A | A | A | A |
| Example 8 | 2.38 | 54 | 0.44 | 100 | A | A | A | A |
| Example 9 | 0.4 | 75 | 0.42 | 100 | A | A | A | A |
| Comparative | 2.38 | 51 | 0.43 | 100 | B | immeasurable | | A |
| Example 1 | | | | | | | | |
| Comparative | 2.38 | 51 | 0.43 | 100 | A | C | A | A |
| Example 2 | | | | | | | | |

| | | | | | | | |
|---|---|---|---|---|---|---|---|
| Comparative | 2.38 | not resolved by | 99 | A | B | A | A |
| Example 3 | | exposure of 500 mJ | | | | | |
| Comparative | 0.4 | not resolved by | 99 | A | B | A | A |
| Example 4 | | exposure of 500 mJ | | | | | |

As apparent from Table 2, the positive photosensitive resin composition of the present invention is excellent in the sensitivity, resolution, residual film ratio and storage stability and when cured, can form a cured film excellent in the heat resistance, adhesion, transmittance and the like.

### INDUSTRIAL APPLICABILITY

According to the present invention, a positive photosensitive resin composition excellent in the sensitivity, resolution, residual film ratio and storage stability, and a cured film forming method using the same can be provided, which are a positive photosensitive resin composition and a cured film forming method using the same, ensuring that when the composition is cured, a cured film excellent in the heat resistance, adhesion, transmittance and the like is obtained.

The entire disclosure of each and every foreign patent application from which the benefit of foreign priority has been claimed in the present application is incorporated herein by reference, as if fully set forth.

1. A positive photosensitive resin composition, comprising:
(A) a resin having an acid-dissociable group represented by formula (1), which is alkali-insoluble or sparingly alkali-soluble and becomes alkali-soluble when the acid-dissociable group is dissociated;
(B) a compound capable of generating an acid upon irradiation with actinic rays at a wavelength of 300 nm or more;
(C) a crosslinking agent; and
(D) an adhesion aid: 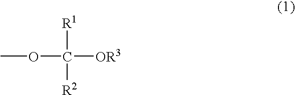
wherein R¹ and R² each independently represents a hydrogen atom, a linear or branched alkyl group which may be substituted or a cycloalkyl group which may be substituted, provided that a case where R¹ and R² both are a hydrogen atom is excluded;
R³ represents a linear or branched alkyl group which may be substituted, a cycloalkyl group which may be substituted or an aralkyl group which may be substituted; and
R¹ and R³ may combine to form a cyclic ether.

2. The positive photosensitive resin composition according to claim 1,
wherein the component (A) contains a constituent unit represented by formula (2) and a constituent unit represented by formula (3): 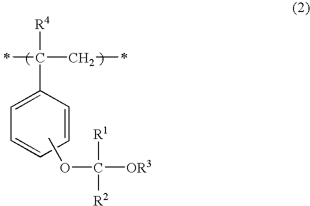
wherein R¹ and R² each independently represents a hydrogen atom, a linear or branched alkyl group which may be substituted or a cycloalkyl group which may be substituted, provided that a case where R¹ and R² both are a hydrogen atom is excluded;
R³ represents a linear or branched alkyl group which may be substituted, a cycloalkyl group which may be substituted or an aralkyl group which may be substituted;
R¹ and R³ may combine to form a cyclic ether; and
R⁴ represents a hydrogen atom or a methyl group: 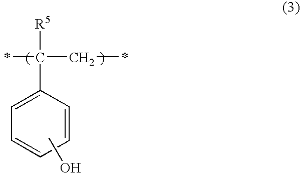
wherein R⁵ represents a hydrogen atom or a methyl group.

3. The positive photosensitive resin composition according to claim 1, comprising:
a compound represented by formula (4) as the component (B): 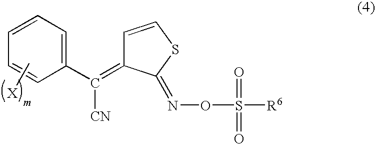
wherein R⁶ represents a linear or branched alkyl group which may be substituted, a cycloalkyl group which may be substituted or an aryl group which may be substituted;
X represents a linear or branched alkyl group which may be substituted, an alkoxy group which may be substituted or a halogen atom; and
m represents an integer of 0 to 3, and when m represents 2 or 3, a plurality of X's may be the same or different.

4. The positive photosensitive resin composition according to claim 1, comprising:
a compound having at least two structures represented by formula (5) as the component (C): 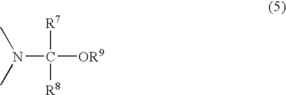
wherein R⁷ and R⁸ each independently represents a hydrogen atom, a linear or branched alkyl group or a cycloalkyl group; and
R⁹ represents a linear or branched alkyl group, a cycloalkyl group, an aralkyl group or an acyl group.

5. The positive photosensitive resin composition according to claim 1, comprising:
at least one compound selected from the group consisting of a compound represented by formula (6), a compound represented by formula (7) and a compound represented by formula (8) as the component (C): 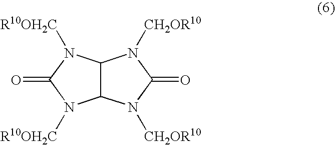
wherein R¹⁰ each independently represents a linear or branched alkyl group, a cycloalkyl group or an acyl group: 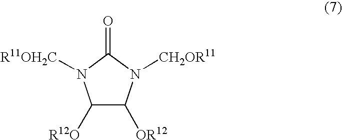
wherein R¹¹ and R¹² each independently represents a linear or branched alkyl group, a cycloalkyl group or an acyl group: 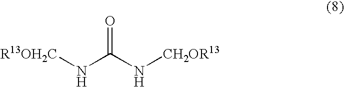
wherein R¹³ each independently represents a linear or branched alkyl group, a cycloalkyl group or an acyl group.

6. A cured film forming method, comprising:
coating and drying the positive photosensitive resin composition according to claim 1 to form a film coating;
exposing the film coating through a mask by using actinic rays at a wavelength of 300 nm or more;
developing the film coating by using an alkali developer to form a pattern; and
heat-treating the obtained pattern.

7. The cured film forming method according to claim 6, which further comprises:
performing entire surface exposure after developing the film coating by using an alkali developer to form a pattern but before heat-treating the obtained pattern.

8. The positive photosensitive resin composition according to claim 1,
wherein the component (C) is contained in an amount of 2 to 100 parts by mass per 100 parts by mass of the component (A).

9. The positive photosensitive resin composition according to claim 1,
wherein the component (D) is contained in an amount of 0.1 to 20 parts by mass per 100 parts by mass of the component (A).
